(19) United States
(12) Patent Application Publication
(10) Pub. No.: US 2013/0128194 A1
(43) Pub. Date: May 23, 2013

(54) LIQUID CRYSTAL PANEL AND MANUFACTURING METHOD THEREOF

(71) Applicants: Zuomin Liao, Shenzhen (CN); Minghung Shih, Shenzhen (CN)

(72) Inventors: Zuomin Liao, Shenzhen (CN); Minghung Shih, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/380,908

(22) PCT Filed: Nov. 24, 2011
(86) PCT No.: PCT/CN2011/082830

§ 371 Date: Dec. 27, 2011

(30) Foreign Application Priority Data
Nov. 18, 2011 (CN) 201110369510.2

(51) Int. Cl. G02F 1/1335; H01L 33/08; G02F 1/1333

(52) U.S. Cl. 349/106; 349/138; 438/30; 257/E33.012

(57) ABSTRACT

Disclosed are a liquid crystal panel and a manufacturing method thereof. The liquid crystal panel includes a first substrate and a second substrate. The first substrate has a first display area and a first surrounding area. The second substrate has a second display area and a second surrounding area. A first and second electrode layers are respectively formed in the first and second surrounding areas. At least one coating layer is formed in at least one of the first surrounding area and the second surrounding area. The at least one of the first electrode layer and the second electrode layer is protruded a contact distance of the coating layer, so that the first electrode layer contacts the second electrode after the first substrate is assembled to the second substrate. The present invention decreases the cost and improves the display quality of the liquid crystal panel.

### BACKGROUND OF THE INVENTION

1. Field of the Invention

The present invention generally relates to a liquid crystal display technology field, and more particularly to a liquid crystal panel and a manufacturing method thereof.

2. Description of Prior Art

With the progressive development of liquid crystal display technology, requirements for functions of a liquid crystal display are getting higher and higher.

The liquid crystal display comprises a display area and a surrounding area which surrounds the display area. The surrounding area is utilized for electrically connected with an external power. Please refer to FIG. 1, which shows a cross-sectional view of a liquid crystal panel in the prior arts. The liquid crystal panel comprises a thin film transistor (TFT) substrate 11 and a color filter (CF) substrate 21.

A first electrode layer 12 is formed on an inner side of the TFT substrate 11. A second electrode layer 22 is formed on an inner side of the CF substrate 21. A gold adhesion 30 is formed between the first electrode layer 12 and the second electrode layer 22.

In a vertical alignment (VA) mode or a twisted nematic (TN) mode, electricity is applied to the first electrode layer 12 in a surrounding area of the TFT substrate 11. The first electrode layer 12 in the surrounding area provides an electric potential for the first electrode layer in a display area (not shown). Meanwhile, the electric potential is conducted to the second electrode layer 22 in a surrounding area of the CF substrate 21 through the gold adhesion 30 by the first electrode layer 12 in the surrounding area, and then the electric potential is conducted to the second electrode layer 22 in a display area (now shown) of the CF substrate 21. Finally, a voltage difference is formed between the display area of the TFT substrate 11 and the display area of the CF substrate 21 by controlling the electric potential. The voltage difference drives liquid crystal molecules between the TFT substrate 11 and the CF substrate 21 to align as an optical grating.

Apparently, the gold adhesion 30 is required to be coated between the TFT substrate 11 and the CF substrate 21 which are finished being manufactured. Since the coating technology of the gold adhesion 30 is complicated and the cost of the gold adhesion 30 is higher, the manufacturing cost of the liquid crystal panel is higher. Furthermore, when the gold adhesion 30 is not coated uniformly, mura phenomenon appears on the liquid crystal panel.

### SUMMARY OF THE INVENTION

An objective of the present invention is to provide a liquid crystal panel to solve the technical problem that when the gold adhesion is not coated uniformly, the mura phenomenon appears on the liquid crystal panel. As a result, the coating technology of the liquid crystal panel can be simplified and the cost can be decreased.

To solve the above-mentioned problem and to achieve the above-mentioned beneficial technical effect, the present invention constructs a liquid crystal panel. The liquid crystal panel comprises a first substrate and a second substrate. The first substrate has a first display area and a first surrounding area. The second substrate has a second display area corresponding to the first display area and a second surrounding area corresponding to the first surrounding area. A first electrode layer is formed in the first surrounding area. A second electrode layer is formed in the second surrounding area.

A coating layer or layers excluding the first electrode layer are formed in the first surrounding area. A maximum vertical distance between the formed coating layer or layers and an inner side of the first substrate is a first contact distance. A coating layer or layers excluding the second electrode layer are formed in the second surrounding area. A maximum vertical distance between the formed coating layer or layers and an inner side of the second substrate is a second contact distance.

A sum of the first contact distance, the second contact distance, a thickness of the first electrode layer, and a thickness of the second electrode layer is equal to a distance between the inner side of the first substrate and the inner side of the second substrate, so that the first electrode layer contacts the second electrode after the first substrate is assembled to the second substrate.

The formed coating layer or layers excluding the first electrode layer in the first surrounding area comprise one or more of a gate electrode insulating layer, a semiconductor layer, an ohmic contact layer, and a protective layer. The formed coating layer or layers excluding the second electrode layer in the second surrounding area comprise one or more of a light-shielding layer and a color resist layer.

In the liquid crystal panel of the present invention, the color resist layer comprises one of a red resist layer, a green resist layer, and a blue resist layer or is formed by stacking at least two of the red resist layer, the green resist layer, and the blue resist layer.

Another objective of the present invention is to provide a liquid crystal panel to solve the technical problem that when the gold adhesion is not coated uniformly, the mura phenomenon appears on the liquid crystal panel. As a result, the coating technology of the liquid crystal panel can be simplified and the cost can be decreased.

To solve the above-mentioned problem and to achieve the above-mentioned beneficial technical effect, the present invention constructs a liquid crystal panel. The liquid crystal panel comprises a first substrate and a second substrate. The first substrate has a first display area and a first surrounding area. The second substrate has a second display area corresponding to the first display area and a second surrounding area corresponding to the first surrounding area. A first electrode layer is formed in the first surrounding area. A second electrode layer is formed in the second surrounding area.

At least one coating layer is formed in at least one of the first surrounding area and the second surrounding area. The at least one of the first electrode layer and the second electrode layer is protruded a contact distance of the coating layer, so that the first electrode layer contacts the second electrode after the first substrate is assembled to the second substrate.

In the liquid crystal panel of the present invention, the at least one coating layer excluding the first electrode layer is formed in the first surrounding area. A maximum vertical distance between the formed coating layer and an inner side of the first substrate is a first contact distance.

The at least one coating layer excluding the second electrode layer is formed in the second surrounding area. A maximum vertical distance between the formed coating layer and an inner side of the second substrate is a second contact distance.

A sum of the first contact distance, the second contact distance, a thickness of the first electrode layer, and a thickness of the second electrode layer is equal to a distance between the inner side of the first substrate and the inner side of the second substrate.

In the liquid crystal panel of the present invention, the formed coating layer excluding the first electrode layer in the first surrounding area comprises one or more of a gate electrode insulating layer, a semiconductor layer, an ohmic contact layer, and a protective layer.

In the liquid crystal panel of the present invention, the formed coating layer excluding the second electrode layer in the second surrounding area comprises one or more of a light-shielding layer and a color resist layer.

In the liquid crystal panel of the present invention, the color resist layer comprises one of a red resist layer, a green resist layer, and a blue resist layer or is formed by stacking at least two of the red resist layer, the green resist layer, and the blue resist layer.

Another objective of the present invention is to provide a liquid crystal panel to solve the technical problem that when the gold adhesion is not coated uniformly, the mura phenomenon appears on the liquid crystal panel. As a result, the coating technology of the liquid crystal panel can be simplified and the cost can be decreased.

To solve the above-mentioned problem and to achieve the above-mentioned beneficial technical effect, the present invention constructs a manufacturing method of a liquid crystal panel. The method comprises the following steps:

providing a first substrate and a second substrate, the first substrate having a first display area and a first surrounding area, the second substrate having a second display area corresponding to the first display area and a second surrounding area corresponding to the first surrounding area;

forming a coating layer in the first surrounding area, the formed coating layer at least comprising a first electrode layer;

forming a coating layer in the second surrounding area, the formed coating layer at least comprising a second electrode layer;

forming at least one coating layer in at least one of the first surrounding area and the second surrounding area, so that the at least one of the first electrode layer and the second electrode layer is protruded a contact distance of the coating layer;

assembling the first substrate to the second substrate, so that the first electrode layer contacts the second electrode.

In the manufacturing method of the liquid crystal panel of the present invention, the step of forming the at least one coating layer in the at least one of the first surrounding area and the second surrounding area, so that the at least one of the first electrode layer and the second electrode layer is protruded a contact distance of the coating layer specifically comprises:

forming the coating layer excluding the first electrode layer in the first surrounding area, so that a maximum vertical distance between the formed coating layer and an inner side of the first substrate is a first contact distance;

forming the coating layer excluding the second electrode layer in the second surrounding area, so that a maximum vertical distance between the formed coating layer and an inner side of the second substrate is a second contact distance;

a sum of the first contact distance, the second contact distance, a thickness of the first electrode layer, and a thickness of the second electrode layer is equal to a distance between the inner side of the first substrate and the inner side of the second substrate.

In the manufacturing method of the liquid crystal panel of the present invention, the formed coating layer excluding the first electrode layer in the first surrounding area comprises one or more of a gate electrode insulating layer, a semiconductor layer, an ohmic contact layer, and a protective layer.

In the manufacturing method of the liquid crystal panel of the present invention, the formed coating layer excluding the second electrode layer in the second surrounding area comprises one or more of a light-shielding layer and a color resist layer.

In the manufacturing method of the liquid crystal panel of the present invention, the color resist layer comprises one of a red resist layer, a green resist layer, and a blue resist layer or is formed by stacking at least two of the red resist layer, the green resist layer, and the blue resist layer.

Comparing with the prior arts, the coating layer or layers excluding the electrode layers in the surrounding areas of the first or second substrate are remained in the present invention. The first or second electrode layer corresponding to the remained coating layer or layers is protruded a contact distance of the remained coating layer or layers, so that the first electrode layer in the first surrounding area contacts with the second electrode layer in the second surrounding area to achieve electrical conduction after the first substrate is assembled to the second substrate. As a result, the coating technology of the gold adhesion in the prior arts can be omitted, and the cost can be decreased. Furthermore, the mura phenomenon resulted from the non-uniform coating of the gold adhesion can be avoided for greatly improving the image display quality of the liquid crystal panel.

For a better understanding of the aforementioned content of the present invention, preferable embodiments are illustrated in accordance with the attached figures for further explanation:

### BRIEF DESCRIPTION OF THE DRAWINGS

FIG. 1 shows a cross-sectional view of a liquid crystal panel in the prior arts;

FIG. 2 shows a flow chart of a preferable embodiment of a liquid crystal panel according to the present invention;

FIGS. 3A-3E show processes of forming a first substrate of a preferable embodiment according to the present invention;

FIGS. 4A-4E show processes of forming a second substrate of a preferable embodiment according to the present invention;

FIG. 5 shows a liquid crystal panel of a preferable embodiment according to the present invention.

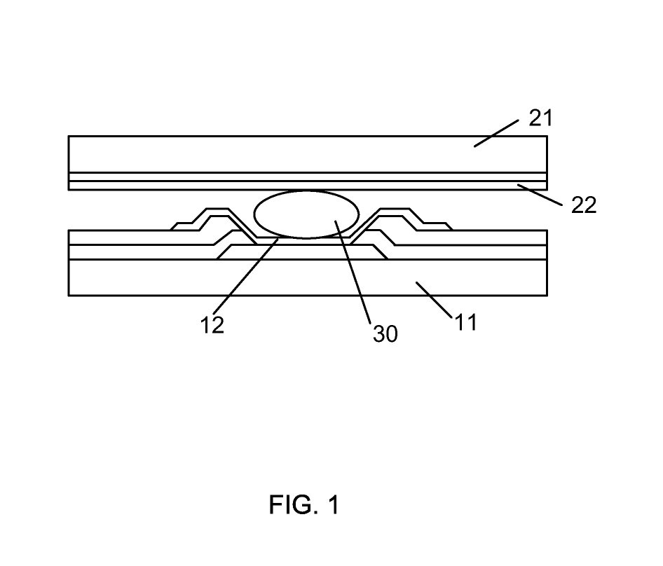

### DETAILED DESCRIPTION OF THE INVENTION

The following descriptions for the respective embodiments are specific embodiments capable of being implemented for illustrations of the present invention with referring to appended figures.

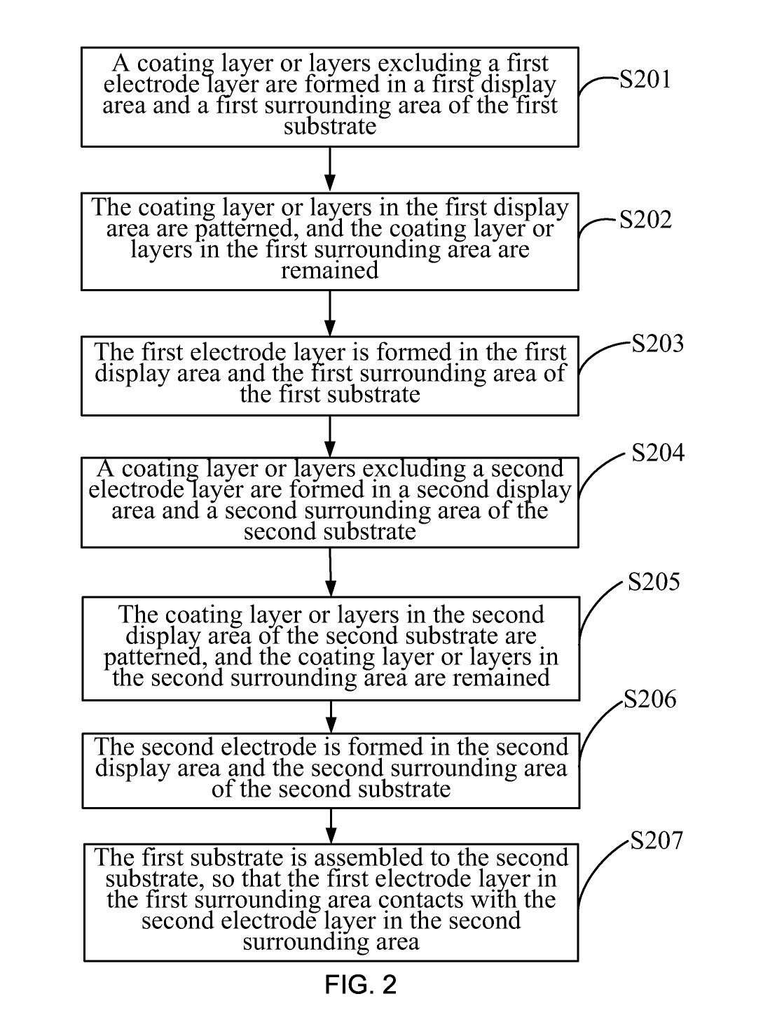

FIG. 2 shows a flow chart of a preferable embodiment of a liquid crystal panel according to the present invention.

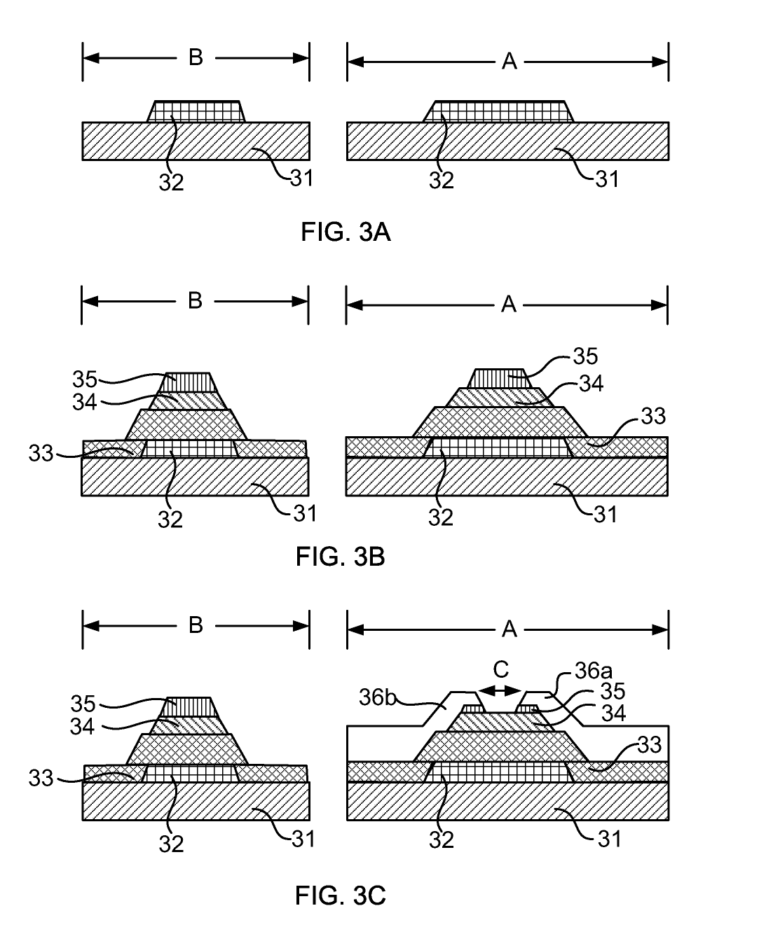

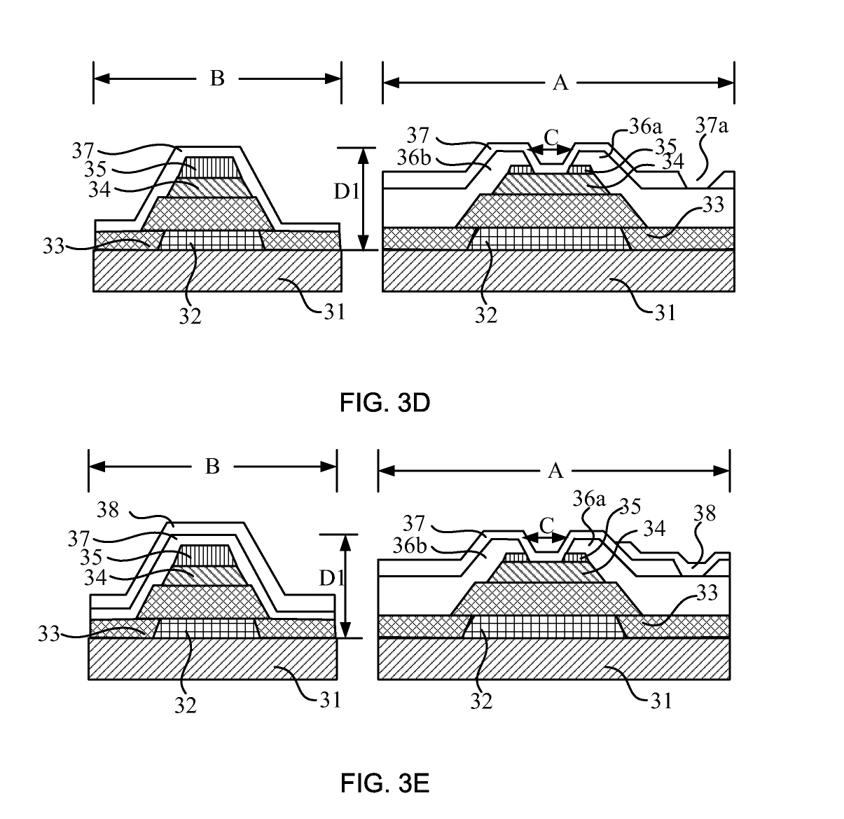

In step S201, a first substrate (TFT substrate) is provided. A coating layer or layers excluding a first electrode layer are formed in a first display area A and a first surrounding area B of the first substrate (please refer to FIGS. 3A-3E).

For example, a gate electrode, a gate electrode insulating layer, a semiconductor layer, an ohmic contact layer, and a protective layer are sequentially formed in the first display area A and the first surrounding area B of the first substrate.

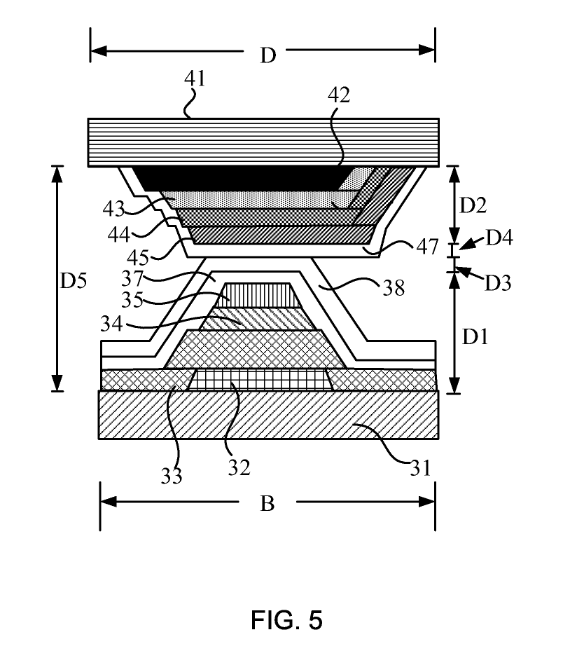

In step S202, the coating layer or layers in the first display area A are patterned, and the coating layer or layers in the first surrounding area B are remained so that a maximum vertical distance between the remained coating layer or layers in the first surrounding area B and an inner side of the first substrate is a first contact distance (please refer to FIG. 5).

In the embodiment implementing processes, the remained coating layer or layers in the first surrounding area B can be patterned for controlling a shape of the remained coating layer or layers, such as a pyramid shape.

In step S203, the first electrode layer is formed in the first display area A and the first surrounding area B of the first substrate, and the first electrode layer in the first display area A is patterned to form an active element matrix in the first display area A.

Meanwhile, the remained coating layer or layers in the first surrounding area B comprises one or more of a gate electrode insulating layer, an amorphous silicon layer, an ohmic contact layer, and the first electrode layer.

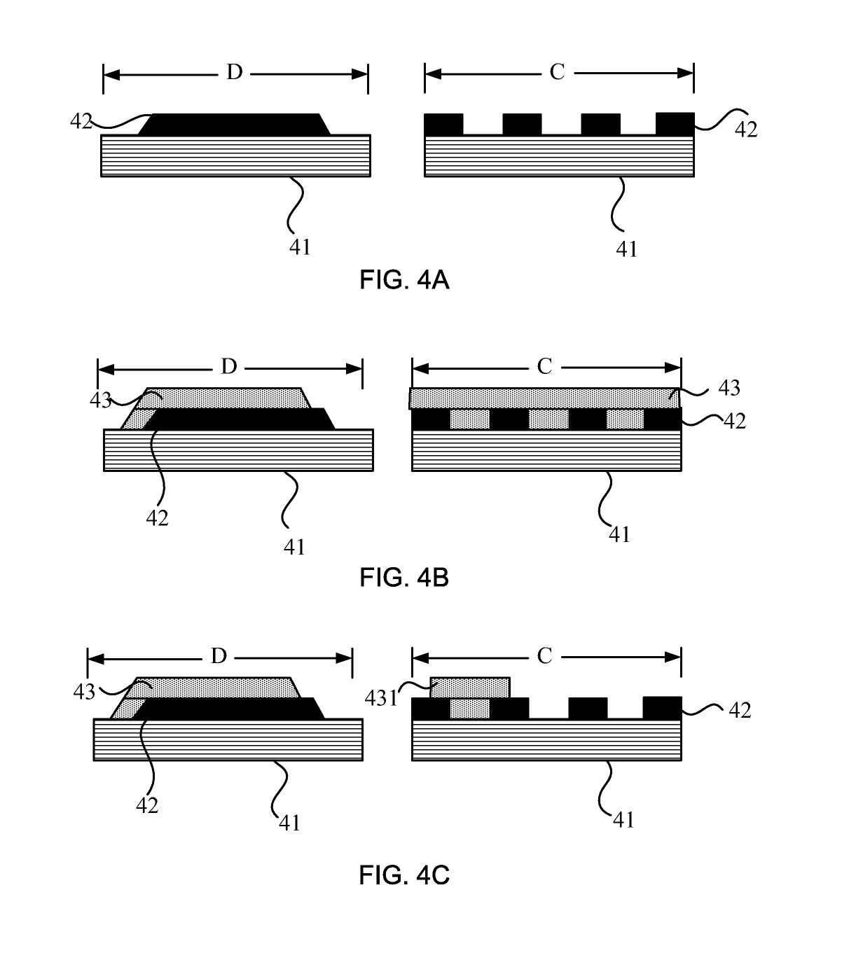

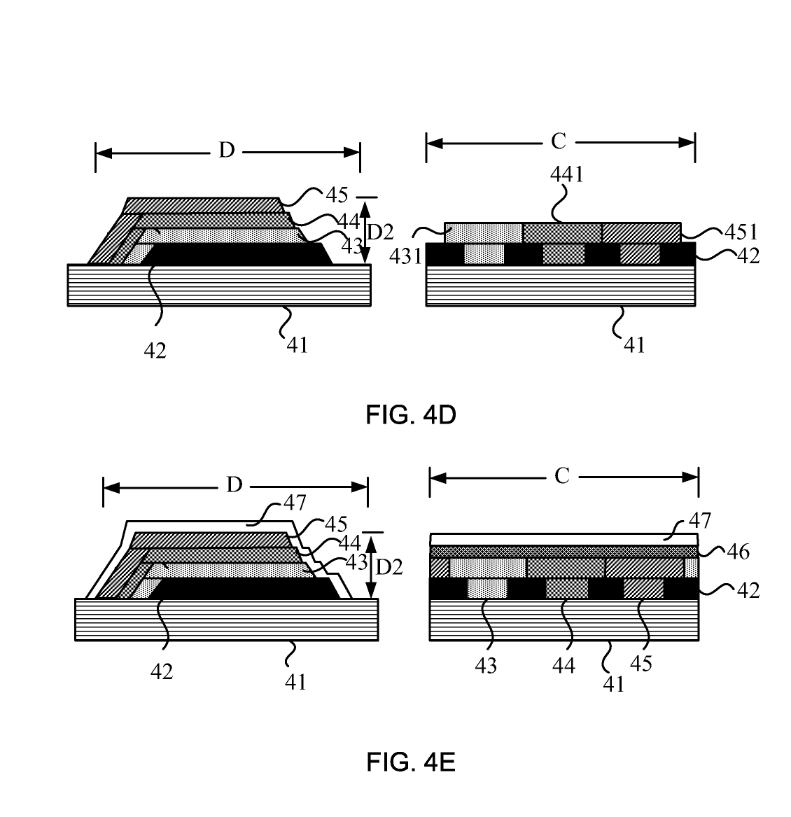

In step S204, a second substrate (CF substrate) is provided. A coating layer or layers excluding a second electrode layer are formed in a second display area C and a second surrounding area D of the second substrate (please refer to FIGS. 4A-4E).

The second display area C of the second substrate is corresponding to the first display area A of the first substrate, and the second surrounding area D of the second substrate is corresponding to the first surrounding area B of the first substrate.

In step S205, the coating layer or layers in the second display area C of the second substrate are patterned, and the coating layer or layers in the second surrounding area D are remained.

In the embodiment implementing processes, the remained coating layer or layers in the second surrounding area D can be patterned for controlling a shape of the remained coating layer or layers, such as a pyramid shape. A maximum vertical distance between the remained coating layer or layers and an inner side of the second substrate is controlled to be a second contact distance (please refer to FIG. 5).

In step S206, the second electrode is formed in the second display area C and the second surrounding area D of the second substrate.

Meanwhile, the remained coating layer or layers in the second surrounding area D comprise one or more of a black matrix (BM) layer and a color resist layer. The remained color resist layer comprises one or more of a red (R) resist layer, a green (G) resist layer, and a blue (B) resist layer. The remained coating layer or layers in the second surrounding area D comprise the second electrode layer.

In the present embodiment, the first contact distance and the second contact distance form a contact distance which meets the following condition that a sum of the first contact distance D1, the second contact distance D2, a thickness D3 of the first electrode layer, and a thickness D4 of the second electrode layer is equal to a distance between the first substrate and the second substrate (please refer to FIG. 5).

In step S207, the first substrate is assembled to the second substrate, so that the first electrode layer in the first surrounding area B contacts with the second electrode layer in the second surrounding area D.

In the present invention, the coating layer or layers in the surrounding area of the first substrate and the coating layer or layers in the surrounding area of the second substrate are remained. After the first substrate is assembled to the second substrate, the first electrode layer in the first surrounding area contacts with the second electrode layer in the second surrounding area to achieve electrical conduction. As a result, the coating technology of the gold adhesion in the prior arts can be omitted, and the cost can be decreased. Furthermore, the mura phenomenon resulted from the non-uniform coating of the gold adhesion can be avoided for greatly improving the image display quality of the liquid crystal panel.

Please refer to FIGS. 3A-3E, which show processes of forming a first substrate of a preferable embodiment.

Please refer to FIG. 3A, a gate electrode 32 is formed in a display area A and a surrounding area B of the first substrate 31. The gate electrode 32 is formed by a first mask process.

Please refer to FIG. 3B, a gate electrode insulating layer 33, a semiconductor 34, and an ohmic contact layer 35 are sequentially formed on the substrate 31. All of the above-mentioned coating layers cover the display area first A and the first surrounding area B of the first substrate 31. The semiconductor layer 34 and the ohmic contact layer 35 in the first display area and the first surrounding area are patterned to form a semiconductor island on the gate electrode insulating layer 33 by lithography of a second mask process.

Please refer to FIG. 3C, by lithography of a third mask process, a drain electrode 36a and a source electrode 36b are formed on the semiconductor island in the first display area A, and a channel C is formed between the drain electrode 36a and the source electrode layer 36b.

Please refer to FIG. 3D, by lithography of a fourth mask process, a protective layer 37 is formed on the channel C, the drain electrode 36a, and the source electrode 36b. The protective layer 37 has at least one opening 37a for exposing a part of the drain electrode 36a. The protective layer 37 is formed in the first surrounding area B as well. The gate electrode insulating layer 33, the semiconductor layer 34, the ohmic contact layer 35, and the protective layer 37 in the first surrounding area B are remained in the first surrounding area B, and a maximum vertical distance between protective layer 37 and an inner side of the first substrate 31 is a first contact distance D1.

Please refer to FIG. 3E, by lithography of a fifth mask process, a first electrode layer 38 is formed on the protective layer 37. Since the first electrode layer 38 covers the opening 37a (please refer to FIG. 3D), the first electrode layer 38 can be electrically connected with the drain electrode 36a through the opening 37a for achieving to manufacture an active element (TFT) in the first display area A of the first substrate 31. In the lithography of the fifth mask process, the first electrode layer 38 is formed on the protective layer 37 of the first surrounding area B as well. The gate electrode 32, the gate electrode insulating layer 33, the semiconductor layer 34, the ohmic contact layer 35, and the protective layer 37 in the first surrounding area B are remained between the first electrode layer 38 and the first substrate 31.

In the present embodiment, the active element (TFT) matrix of the first substrate 31 is manufactured by five mask processes. In another embodiment, the active element matrix can be manufactured by four or less mask processes.

Please refer to FIGS. 4A-4E, which show processes of forming a second substrate of a preferable embodiment.

Please refer to FIG. 4A, a BM layer 42 (i.e. a light-shielding layer) is formed in a second display area C and a second surrounding area D of the second substrate 41, the BM layer 42 in the second display area C is lithographed to form openings, and the BM layer 42 in the second surrounding area D is remained.

Please refer to FIG. 4B, an R (red color) resist layer 43 is formed in the second display area C and the second surrounding area D.

Please refer to FIG. 4C, the R resist layer 43 is lithographed to form a patterned R resist layer 431, and the R resist layer 43 in the second surrounding area D is remained.

Please refer to FIG. 4D, a G (green color) resist layer 44 and a B (blue color) 45 are sequentially formed in the second display area C and the second surrounding area D. The G resist layer 44 and the B resist layer 45 in the second display area C are lithographed to form a patterned G resist layer 441 and a patterned B resist layer 451, and the G resist layer 44 and the B resist layer 45 in the second surrounding area D are remained.

Please refer to FIG. 4E, an overcoating layer 46 and a second electrode layer 47 are sequentially formed in the second display area C, while the second electrode layer 47 is formed in the second surrounding area D. The BM layer 42, the R resist layer 43, the G resist layer 44, and the B resist layer 45 in the second surrounding area D are remained between the second electrode layer 47 and the second substrate 41. A maximum vertical distance between the B resist layer and an inner side of the second substrate 41 is a second contact distance D2.

Please refer to FIG. 5, which shows a structural diagram of a preferable embodiment of a liquid crystal panel according to the present invention.

The liquid crystal panel comprises the first substrate 31 and the second substrate 41. The first substrate 31 has the first display area A and the first surrounding area B (as shown in FIGS. 3A-3E), while the second substrate 41 has the second display area C and the second surrounding area D (as shown in FIGS. 4A-4E).

In the embodiment of FIG. 5, The gate electrode 32, the gate electrode insulating layer 33, the semiconductor layer 34, the ohmic contact layer 35, the protective layer 37, and the first electrode layer 38 are sequentially formed in the first surrounding area B. The maximum vertical distance between the protective layer 37 and the inner side of the first substrate 31 is the first contact distance D1.

In the embodiment of FIG. 5, the BM layer 42, the R resist layer 43, the G resist layer 44, the B resist layer 45, and the second electrode layer 47 are sequentially formed on the second substrate 41. The maximum vertical distance between the B resist layer 45 and the inner side of the second substrate 41 is the second contact distance D2.

In the present embodiment, the first contact distance D1 and the second contact distance D2 form a contact distance which meets the following condition that a sum of the first contact distance D1, the second contact distance D2, a thickness D3 of the first electrode layer 38, and a thickness D4 of the second electrode layer 47 is equal to a distance D5 between the inner side of the first substrate 31 and the inner side of the second substrate 41.

In the embodiment implementing processes, as long as the first contact distance D1 can be formed, the coating layer or layers excluding the first electrode layer 38 can comprise one or more of the gate electrode insulating layer 33, the semiconductor layer 34, the ohmic contact layer 35, and the protective layer 37 and are not listed in detail.

In the embodiment implementing processes, as long as the second contact distance D2 can be formed, the coating layer or layers excluding the second electrode layer 47 can comprise one or more of the BM layer 42, the R resist layer 43, the G resist layer 44, and the B resist layer 45 and are not listed in detail.

In the processes of forming the first substrate 31 of the present embodiment, the maximum vertical distance between the coating layer or layers excluding the first electrode layer 38 and the inner side of the first substrate 31 is formed to be the first contact distance D1 by remaining the coating layer or layers in the first surrounding area B of the first substrate 31, and the remained coating layer or layers at least comprise the first electrode layer 38; In the processes of forming the second substrate 41, the maximum vertical distance between the coating layer or layers excluding the second electrode layer 47 and the inner side of the second substrate 41 is formed to be the second contact distance D2 by remaining the coating layer or layers in the second surrounding area D of the second substrate 41, and the remained coating layer or layers at least comprise the second electrode layer 47. The sum of the first contact distance D1, the second contact distance D2, the thickness D3 of the first electrode layer 38, and the thickness D4 of the second electrode layer 47 is equal to the distance D5 between the inner side of the first substrate 31 and the inner side of the second substrate 41. Accordingly, after the first substrate 31 is assembled to the second substrate 41, the first electrode layer 38 of the first substrate 31 contacts the second electrode layer 47 of the second substrate 41. When electricity is applied to the first electrode layer 38 in the first surrounding area B of the first substrate 31, the first electrode layer 38 in the first surrounding area B provides an electric potential for the first electrode layer 38 in the display area A. The electric potential is conducted to the second electrode layer 47 in the second display area C through the second electrode layer 47 in the second surrounding area D. Finally, a voltage difference is formed between the first electrode layer 38 in the first display area A and the second electrode layer 47 in the second display area C by controlling the electric potential. The voltage difference drives liquid crystal molecules between the first substrate 31 and the second substrate 41 to align as an optical grating.

In the present invention, the coating layer or layers in the surrounding area of the first substrate and the coating layer or layers in the surrounding area of the second substrate are remained. After the first substrate is assembled to the second substrate, the first electrode layer in the first surrounding area contacts with the second electrode layer in the second surrounding area to achieve electrical conduction. As a result, the coating technology of the gold adhesion in the prior arts can be omitted, and the cost can be decreased. Furthermore, the mura phenomenon resulted from the non-uniform coating of the gold adhesion can be avoided for greatly improving the image display quality of the liquid crystal panel.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A liquid crystal panel, the liquid crystal panel comprising a first substrate and a second substrate, the first substrate having a first display area and a first surrounding area, the second substrate having a second display area corresponding to the first display area and a second surrounding area corresponding to the first surrounding area, a first electrode layer being formed in the first surrounding area, a second electrode layer being formed in the second surrounding area, characterized in that a coating layer or layers excluding the first electrode layer are formed in the first surrounding area, a maximum vertical distance between the formed coating layer or layers and an inner side of the first substrate is a first contact distance; a coating layer or layers excluding the second electrode layer are formed in the second surrounding area, a maximum vertical distance between the formed coating layer or layers and an inner side of the second substrate is a second contact distance;
a sum of the first contact distance, the second contact distance, a thickness of the first electrode layer, and a thickness of the second electrode layer is equal to a distance between the inner side of the first substrate and the inner side of the second substrate, so that the first electrode layer contacts the second electrode after the first substrate is assembled to the second substrate;
the formed coating layer or layers excluding the first electrode layer in the first surrounding area comprise one or more of a gate electrode insulating layer, a semiconductor layer, an ohmic contact layer, and a protective layer; the formed coating layer or layers excluding the second electrode layer in the second surrounding area comprise one or more of a light-shielding layer and a color resist layer.

2. The liquid crystal panel of claim 1, characterized in that the color resist layer comprises one of a red resist layer, a green resist layer, and a blue resist layer or is formed by stacking at least two of the red resist layer, the green resist layer, and the blue resist layer.

3. A liquid crystal panel, the liquid crystal panel comprising a first substrate and a second substrate, the first substrate having a first display area and a first surrounding area, the second substrate having a second display area corresponding to the first display area and a second surrounding area corresponding to the first surrounding area, a first electrode layer being formed in the first surrounding area, a second electrode layer being formed in the second surrounding area, characterized in that at least one coating layer is formed in at least one of the first surrounding area and the second surrounding area, the at least one of the first electrode layer and the second electrode layer is protruded a contact distance of the coating layer, so that the first electrode layer contacts the second electrode after the first substrate is assembled to the second substrate.

4. The liquid crystal panel of 3, characterized in that the at least one coating layer excluding the first electrode layer is formed in the first surrounding area, a maximum vertical distance between the formed coating layer and an inner side of the first substrate is a first contact distance;
the at least one coating layer excluding the second electrode layer is formed in the second surrounding area, a maximum vertical distance between the formed coating layer and an inner side of the second substrate is a second contact distance;
a sum of the first contact distance, the second contact distance, a thickness of the first electrode layer, and a thickness of the second electrode layer is equal to a distance between the inner side of the first substrate and the inner side of the second substrate.

5. The liquid crystal panel of claim 4, characterized in that the formed coating layer excluding the first electrode layer in the first surrounding area comprises one or more of a gate electrode insulating layer, a semiconductor layer, an ohmic contact layer, and a protective layer.

6. The liquid crystal panel of claim 4, characterized in that the formed coating layer excluding the second electrode layer in the second surrounding area comprises one or more of a light-shielding layer and a color resist layer.

7. The liquid crystal panel of claim 6, characterized in that the color resist layer comprises one of a red resist layer, a green resist layer, and a blue resist layer or is formed by stacking at least two of the red resist layer, the green resist layer, and the blue resist layer.

8. A manufacturing method of a liquid crystal panel, characterized in that the method comprises the following steps:
providing a first substrate and a second substrate, the first substrate having a first display area and a first surrounding area, the second substrate having a second display area corresponding to the first display area and a second surrounding area corresponding to the first surrounding area;
forming a coating layer in the first surrounding area, the formed coating layer at least comprising a first electrode layer;
forming a coating layer in the second surrounding area, the formed coating layer at least comprising a second electrode layer;
forming at least one coating layer in at least one of the first surrounding area and the second surrounding area, so that the at least one of the first electrode layer and the second electrode layer is protruded a contact distance of the coating layer;
assembling the first substrate to the second substrate, so that the first electrode layer contacts the second electrode.

9. The manufacturing method of the liquid crystal panel of claim 8, characterized in that the step of forming the at least one coating layer in the at least one of the first surrounding area and the second surrounding area, so that the at least one of the first electrode layer and the second electrode layer is protruded a contact distance of the coating layer specifically comprises:
forming the coating layer excluding the first electrode layer in the first surrounding area, so that a maximum vertical distance between the formed coating layer and an inner side of the first substrate is a first contact distance;
forming the coating layer excluding the second electrode layer in the second surrounding area, so that a maximum vertical distance between the formed coating layer and an inner side of the second substrate is a second contact distance;
a sum of the first contact distance, the second contact distance, a thickness of the first electrode layer, and a thickness of the second electrode layer is equal to a distance between the inner side of the first substrate and the inner side of the second substrate.

10. The manufacturing method of the liquid crystal panel of claim 9, characterized in that the formed coating layer excluding the first electrode layer in the first surrounding area comprises one or more of a gate electrode insulating layer, a semiconductor layer, an ohmic contact layer, and a protective layer.

11. The manufacturing method of the liquid crystal panel of claim 9, characterized in that the formed coating layer excluding the second electrode layer in the second surrounding area comprises one or more of a light-shielding layer and a color resist layer.

12. The manufacturing method of the liquid crystal panel of claim 11, characterized in that the color resist layer comprises one of a red resist layer, a green resist layer, and a blue resist layer or is formed by stacking at least two of the red resist layer, the green resist layer, and the blue resist layer.
